(19) United States
(12) Patent Application Publication
(10) Pub. No.: US 2009/0166318 A1
(43) Pub. Date: Jul. 2, 2009

(54) Method of Fabricating an Integrated Circuit

(76) Inventors: Mihel Seitz, Redebeul (DE); Stephan Wege, Dresden (DE); Mirko Vogt, Dresden (DE); Juergen Voelkel, Langebrueck (DE)

Correspondence Address: SLATER & MATSIL, L.L.P., 17950 PRESTON ROAD, SUITE 1000, DALLAS, TX, 75252, US

(21) Appl. No.: 11/966,975

(22) Filed: Dec. 28, 2007

(51) Int. Cl. H01B 13/00; H01L 21/306; B32B 3/00

(52) U.S. Cl. 216/13; 156/345.19; 156/345.3; 428/141

(57) ABSTRACT

A method of fabricating an integrated circuit includes providing a hard mask that includes at least one first layer and one second layer. An etching step is patterned using the hard mask, and a removal step is performed using an etchant in order to at least partially remove the first layer. The first layer and the second layer are configured in such a way that the first layer is etched by the etchant with a higher etch rate than the second layer.

### BRIEF DESCRIPTION OF THE DRAWINGS

In the accompanying drawings:

FIGS. 1 and 2 illustrate process steps of a method according to a first embodiment of the invention;

FIGS. 3A-5B illustrate process steps of a method according to a second embodiment of the invention;

FIGS. 6A-8B illustrate process steps of a method according to a third embodiment of the invention; and

FIGS. 9-12 illustrate further embodiments of the invention.

### DETAILED DESCRIPTION OF ILLUSTRATIVE EMBODIMENTS

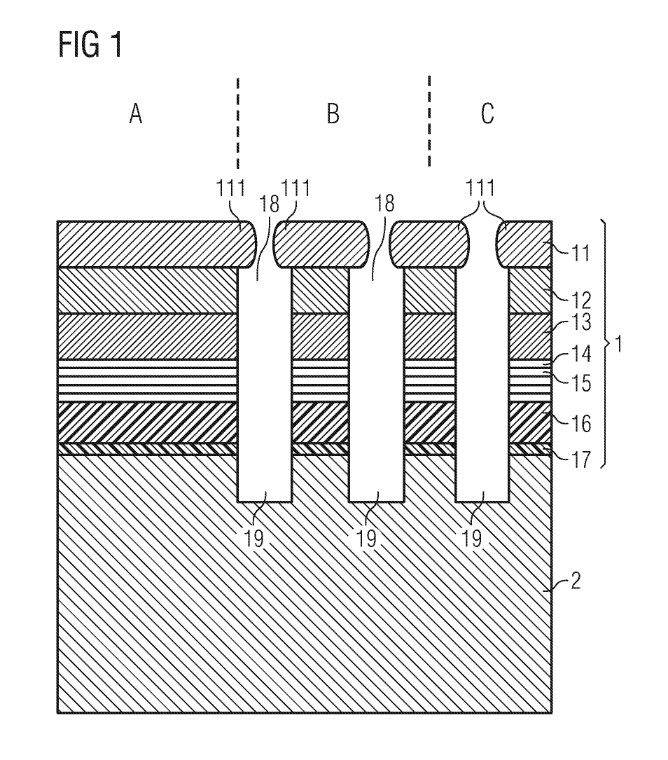

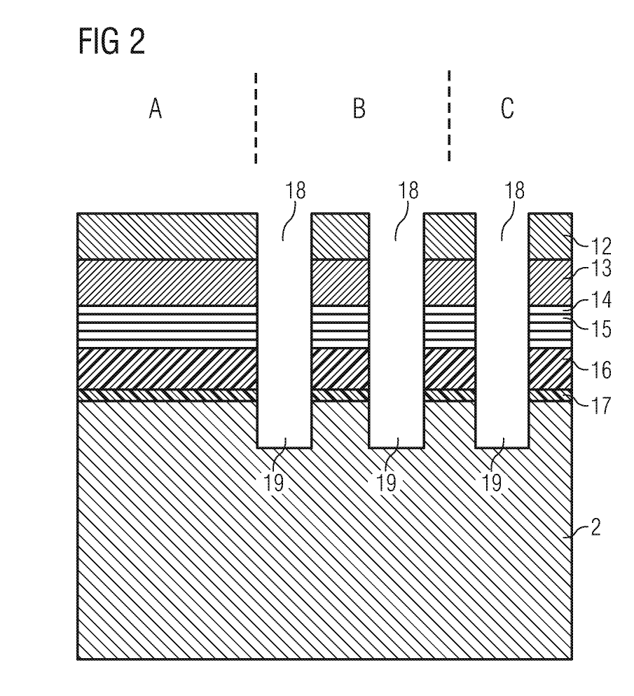

FIGS. 1 and 2 relate to different process steps of a method according to an embodiment of the invention, the method being used for fabricating an integrated circuit. More particularly, FIGS. 1 and 2 each depict different sections A, B and C of the integrated circuit to be fabricated, wherein section A is related to a periphery section of the integrated circuit, section B depicts a sectional view along a first direction, and section C depicts a sectional view along a second direction which is perpendicular to the first direction.

A hard mask layer in the form of hard mask layer stack 1 is arranged on a substrate 2, e.g., a silicon substrate. The hard mask layer stack 1 comprises a plurality of layers including a first layer 11 and a second layer 12, wherein the first layer 11 is arranged above the second layer 12 at the top of layer stack 1.

The layer stack 1 furthermore comprises layer 13 which is arranged below the second layer 12 and which can comprise the same material as the first layer 11. Below layer 13 a sub stack including a plurality of layers 14 comprising a first material and a plurality of layers 15 comprising a second material is disposed, the layers 15 being arranged alternating with the layers 14. In an embodiment the first material is the same as the material of first layer 11 and the second material is the same as the material of the second layer 12. Further, layers 14 and 15 have a thickness that is smaller than the thickness of the first and of the second layers 11, 12.

Between the sub stack comprising the layers 14, 15 and substrate 2, further layers 16 and 17 are arranged. For example, layers 16 and 17 each comprise a material different from layers 11-15. For example, layer 16 can comprise of a composition of silicon and nitride, while layer 17 comprises silicon oxide in order to relieve stress between layer 16 and the substrate 2.

It is noted that the term “substrate” does not refer to a bulk substrate only. It also covers a (bulk) substrate (e.g., a wafer) on which a layer or multiple layers are arranged. For example, a substrate in that sense can comprise additional layers disposed between (bulk) substrate 2 and layers 16 and 17.

As further illustrated in FIG. 1, the hard mask layer stack 1 is structured such that it comprises openings 18. The openings 18 are, e.g., generated lithographically, for example, using a resist mask on top of layer stack 1. The hard mask layer stack 1 is then used to create openings 19 in substrate 2. For this, an etching step is performed such that the plurality of openings 19 is created in substrate 2, wherein each are aligned with one of the openings 18 of the hard mask layer stack 1

In the course of the etching step, a plurality of protrusions 111 of first layer 11 develops adjacent to the openings 18. The protrusions 111 reduce the diameter of the openings 18 such that a choked area is created that derogates the further etching of the openings 19. Protrusions of the kind shown in FIG. 1, e.g., occur during the etching of deep structures (e.g., deep trench structures of a storage element), wherein they may be formed by etch products that deposit at a top region of the sidewalls of openings 18 (i.e., in the region of first layer 11).

Referring to FIG. 2, a removal step is performed that removes the first layer 11 including the protrusions 111. For this, the first and second layers 11, 12 are configured in such a way that the first layer 11 is etched with a higher etch rate than the second layer 12, wherein an appropriate etchant is used. In an example, layer 11 is etched selectively with respect to layer 12 such that the removal step etching automatically stops on the second layer 12. In another example, end point detection is applied in order to detect when the etching reaches second layer 12.

The removal step can be performed either using a wet etching or a dry etching step. It is noted that the protrusions 111 that are not necessarily attacked by the etchant of the removal step directly can be removed with the etching of first layer 11 to which they are attached. In an embodiment, the etchant is chosen to selectively etch the first layer 11 with respect to substrate 2. In a further example dry etching is used that directly etches the protrusions 111 and the first layer 11.

Having removed the protrusions 111, the openings 18 have their original dimensions again such that the etching of substrate 2 continues unobstructed, wherein the critical dimensions with respect to the openings 18 are at the nominal level again and ion scattering is avoided (in case of dry etching of substrate 2).

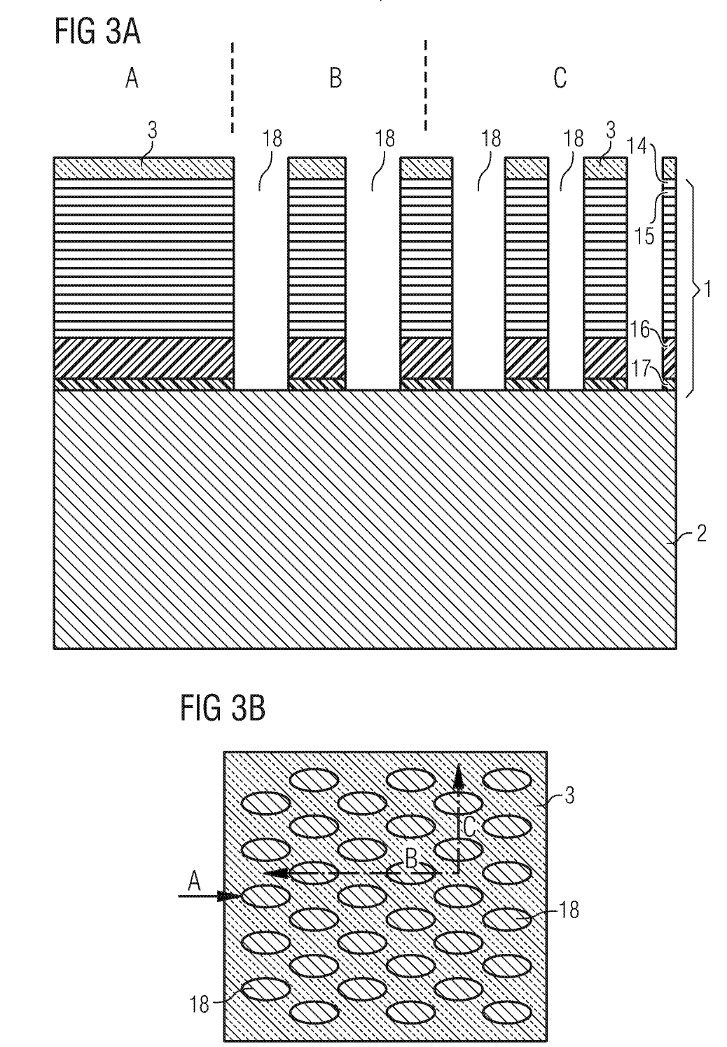

Referring now to FIGS. 3A to 5B, these figures schematically illustrate different process steps of a method according to a second embodiment of the invention, e.g., when fabricating an integrated circuit. Similar to FIGS. 1 and 2, FIGS. 3A to 5A refer to a sectional view of a structure, wherein sectional views along different directions are shown at the same time (sections A, B and C as in FIGS. 1 and 2, wherein sections B and C are also indicated in FIGS. 3B-5B). FIGS. 3B to 5B show corresponding top views of the structure.

According to FIGS. 3A and 3B, a hard mask is arranged on substrate 2, the hard mask comprising a layer stack 1. Layer stack 1 comprises a plurality of first layers 14 (comprising a first material) and a plurality of second layers 15 (comprising a second material) which are arranged alternating with the first layers 14. In this example, layers 14 and 15 essentially have the same thickness (e.g., approximately 2-5 nm). However, in another embodiment, layers 14 and 15 have different thicknesses.

Hard mask layer stack 1 further comprises layers 16 and 17 arranged between the plurality of first and second layers 14, 15 and substrate 2. Layer stack 1 is structured using a structured resist mask 3 such that openings 18 are created within layers 14-17. As depicted in FIG. 3B, the openings 18 have an elliptical cross section and are arranged in a regular (checker board like) pattern.

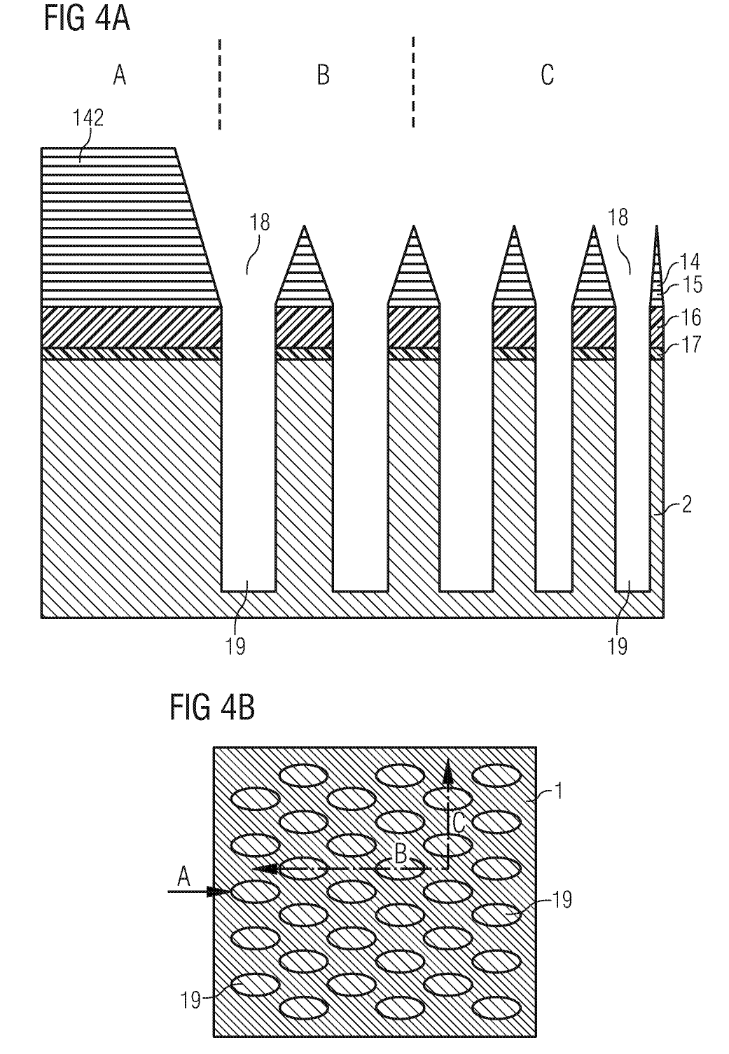

Similar to FIGS. 1 and 2, layer stack 1 is used to create openings 19 in substrate 2 (FIGS. 4A, 4B) by means of an etching step, e.g., a dry etching or a wet etching step. During the etching step a part of the hard mask layer stack 1 is also etched such that openings 18 develop tapered sidewalls in the region of the first and second layers 14, 15. In an embodiment at least the second material (of the second layers 15) is chosen such that the second layers 15 are etched with a lower etch rate by the etchant of the etching step than substrate 2. In an embodiment the second layers 15 are selectively etched with respect to substrate 2, i.e., second layers 15 are hardly etched by the etchant of the etching step. In another embodiment both the first and the second layers 14, 15 are configured to have lower etch rates or to be selectively etched with respect to substrate 2.

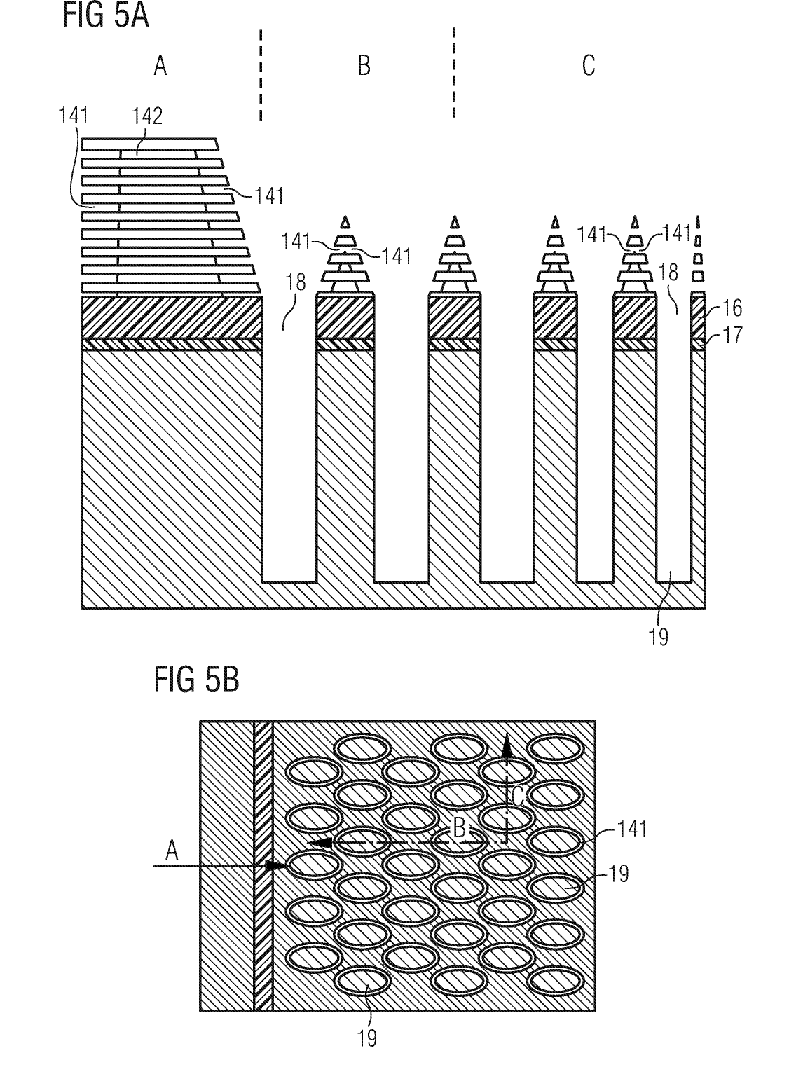

Referring to FIGS. 5A and 5B, a removal step is performed in order to remove the first layers 14, wherein the first material is chosen to be etched by the etchant of the removal step with a higher etch rate than the second material (i.e., the etchability of the first layers 14 is higher than the etchability of the second layers 15 with respect to that etchant).

The etchant intrudes from the openings 18 such that lateral regions 141 of portions 142 of layer 14 which extend between two neighbouring openings 18 are etched first. The second layers 15 are hardly etched by the etchant of the removal step such that neighbouring layers 15 can form a channel for the etchant (which for example is a wet etching agent such as an acid containing liquid), wherein a capillary effect can support the transport of the etchant into the channel and thus the etching of the first layers 14.

Due to the partial removal of the first layers 14, the second layers 15 are at least partially lifted off. Thus, due to the etching of the first layers 14, a removal of the second layers 15 occurs and a complete removal of the upper part (comprising layers 14 and 15) of the hard mask layer stack 1 can be performed. Due to the low etchability in particular of the second layers 15 with respect to substrate 2, layer stack 1 on the one hand provides mask properties during the etching of substrate 2, while on the other hand it can still be removed (due the high etchability of the first layers 14 with respect to the etchant of the removal step).

In an example, the first layers 14 comprise a doped silicon glass (e.g., boron doped silicon glass—BSG) or an undoped silicon glass (USG). The etchant of the removal step could be hydrofluoric acid (HF) in that case. In another example, first layers 14 comprise a first kind of a metal composition and second layers 15 comprise a second kind of a metal composition. For example, layers 14 comprise titanium nitride and layers 15 comprise aluminium oxide.

Although the layer stack 1 of the embodiment according to FIGS. 3A to 5B comprises elliptically shaped openings, the invention can of course be used for the creation of openings having a different shape, e.g., longitudinal openings.

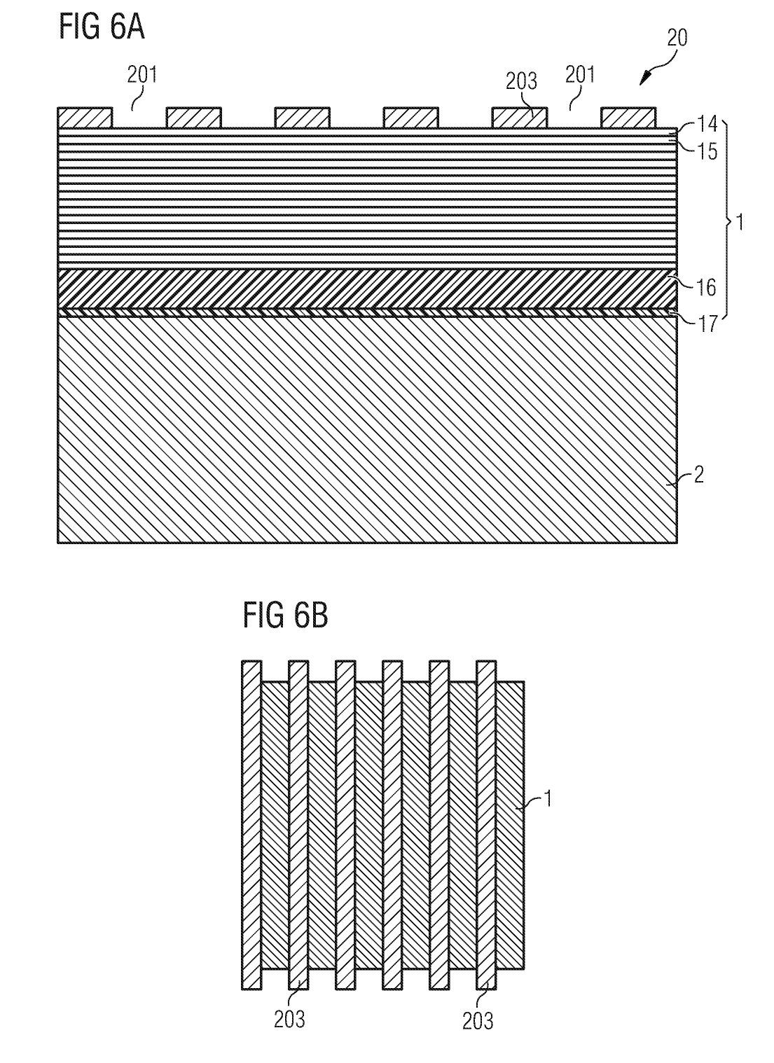

The creation of longitudinal openings is illustrated in FIGS. 6A to 8B, wherein FIGS. 6A to 8A illustrate sectional views and FIGS. 6B to 8B illustrate top views.

More particularly, as in the previous figures, a hard mask in the form of a hard mask layer stack 1 is deposited on a substrate 2 which is to be structured. The hard mask layer stack 1 comprises an upper portion consisting of a plurality of first layers 14 and a plurality of second layers 15 which are arranged alternating with the first layers 14. On top of the hard mask layer stack 1, a mask layer 20 is arranged that is used to structure the hard mask layer stack 1. Mask layer 20 can be a resist mask which is, e.g., structured lithographically or using another hard mask (not shown).

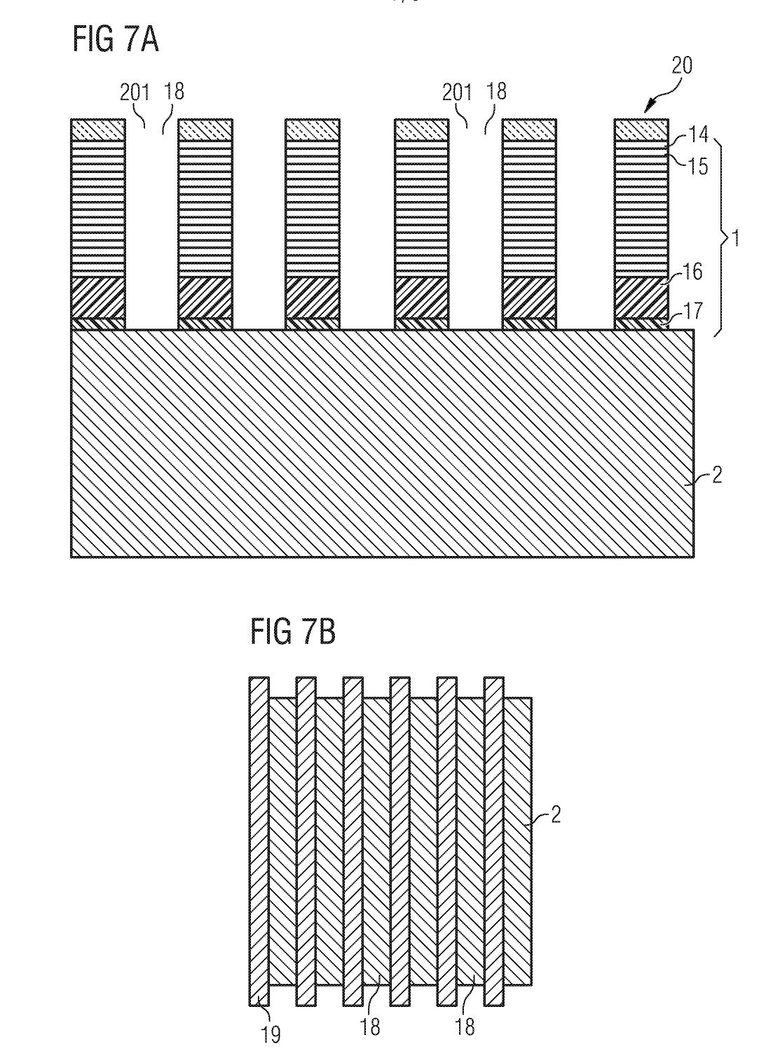

Mask layer 20 comprises a plurality of longitudinal structures 203 (FIGS. 6A and 6B), wherein the space between two neighbouring structures defines openings 201 that are used to structure the hard mask layer stack 1. This is shown in FIGS. 7A and 7B, wherein longitudinal openings 18 are generated.

Using openings 18 of hard mask layer stack 1, longitudinal openings 19 are created in substrate 2 (FIGS. 8A and 8B). After the creation of the openings 19 a removal step is performed in order to remove the hard mask layer stack 1. As in the previous embodiment an etchant of the removal step is used that etches the first layers 14 with a higher etch rate than the second layers 15. The etching starts in lateral regions 141 of layer stack portions 142, wherein the first layers 14 are etched, whereas the second layers 15 are not directly attacked by the removal etching (or at least are attacked less than first layers 14). However, as the etching of the first layers 14 continues, the second layers 15 are lifted off such that the complete upper portion (comprising layers 14 and 15) of the hard mask layer stack 1 can be removed.

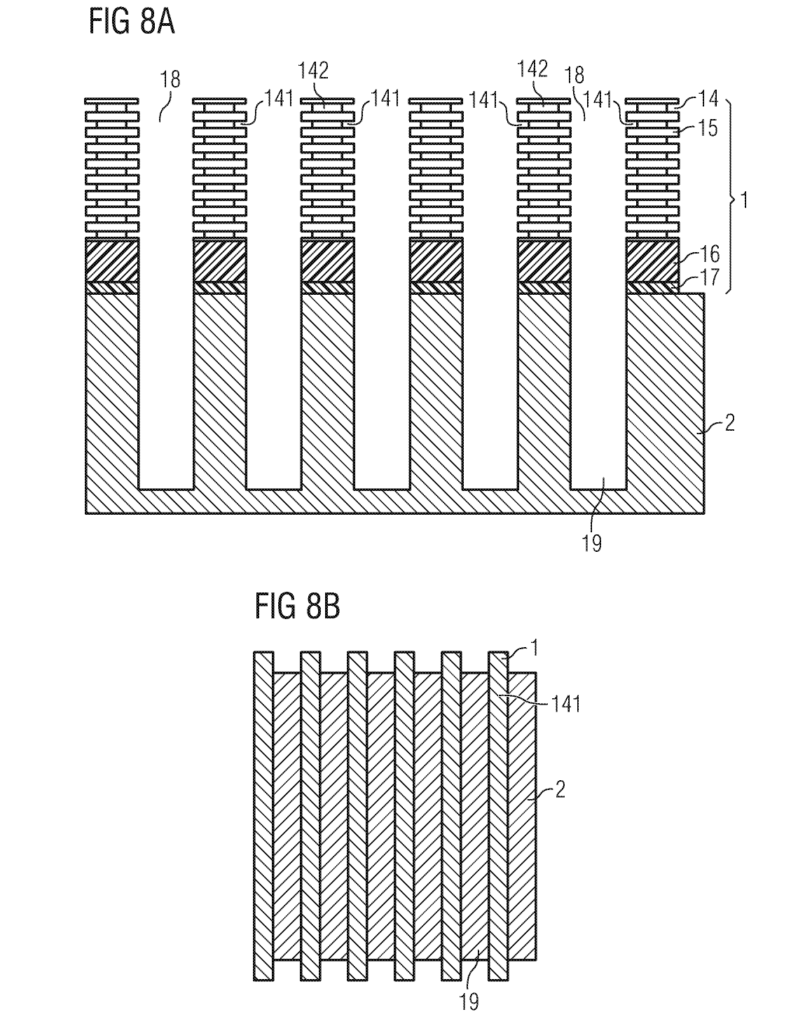

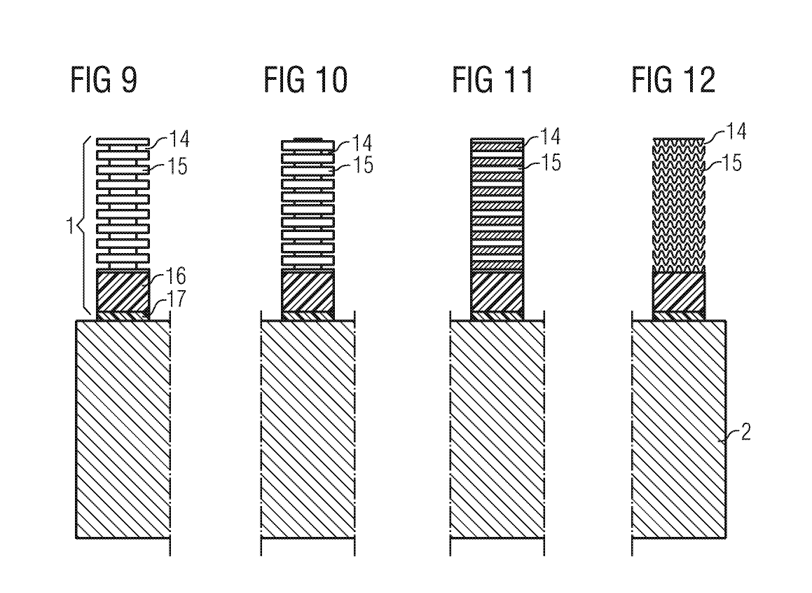

FIGS. 9-12 show different variants of hard mask layer stacks 1. These variants have in common that the layer stack 1 comprises a plurality of first layers 14 and second layers 15. FIG. 9 more particularly refers to a variant, wherein the first layers 14 and second layers 15 have essentially the same thickness. In FIG. 10, the first layers 14 and the second layers 15 have different thicknesses, e.g., first layers 14 are thinner than second layers 15.

According to the embodiment of FIG. 11, layers 14 (shown before the etching) comprise a non-uniform material composition, i.e., the material composition varies locally (along a direction parallel to a substrate surface 2). Due to the varying material composition the etchability of the layer varies locally also. In another embodiment, the material composition of second layers 15 or of both first and second layers 14 and 15 varies locally.

FIG. 12 refers to an embodiment with a non-flat interface between first and second layers 14 and 15. In this embodiment, the interface between neighbouring first and second layers 14 and 15 extends wavelike. Of course, other interface geometries are possible, e.g., having non-regular geometries.

It is noted that the first and second layers of the hard mask layer stack are not restricted to be formed of a certain material. Although undoped and doped glasses are described as an example for creating the first and second layers, other materials of course can be used and are covered by the invention.

What is claimed is:

1. A method of fabricating an integrated circuit, the method comprising:
providing a hard mask comprising at least one first layer and one second layer;
performing an etching step using the hard mask; and
performing a removal step using an etchant in order to at least partially remove the first layer, wherein the first layer is etched by the etchant with a higher etch rate than the second layer.

2. The method according to claim 1, wherein the etching step is performed in order to create a structure in a substrate.

3. The method according to claim 2, wherein the removal step is performed before the creation of the structure is completed and the etching step is continued after removal of the first layer.

4. The method according to claim 1, wherein the etchant of the removal step selectively removes the first layer with respect to the second layer.

5. The method according to claim 1, wherein the first layer and the second layer are arranged in a way such that the second layer is at least partially lifted off when the first layer is at least partially removed with the removal step.

6. The method according to claim 1, wherein the first layer is selectively etched by the etchant of the removal step with respect to a substrate.

7. The method according to claim 1, wherein the etchant of the removal step comprises a wet etch agent.

8. The method according to claim 1, wherein at least one of the first layer and/or the second layer is etched by the etchant of the etching step with a lower etch rate than a substrate that underlies the first and second layers.

9. The method according to claim 1, wherein at least one of the first layer and/or the second layer is selectively etched by the etchant with respect to a substrate that underlies the first and second layers.

10. The method according to claim 1, wherein the etchant comprises a plasma.

11. The method according to claim 1, wherein the hard mask comprises a plurality of first layers and a plurality of second layers arranged alternating with the first layers.

12. The method according to claim 11, wherein the first layers each comprise a first material and the second layers each comprise a second material, and wherein the etchant etches the first material with a higher etch rate than the second material.

13. The method according to claim 1, wherein the first layer comprises a single first layer and the second layer comprises a single second layer.

14. The method according to claim 13, wherein the first layer and the second layer have essentially the same thickness.

15. The method according to claim 13, wherein the first layer and the second layer have different thicknesses.

16. The method according to claim 13, wherein the thickness of at least one of the first layer and/or the second layer is approximately 5-30 nm.

17. The method according to claim 1, further comprising generating at least one opening in the hard mask before the etching step.

18. The method according to claim 17, wherein the opening is a longitudinal opening or a hole.

19. The method according to claim 1, wherein at least one of the first layer and the second layer comprises a metal or a metal oxide.

20. The method according to claim 1, wherein the first layer comprises a first metal composition and the second layer comprises a second metal composition.

21. The method according to claim 20, wherein the first metal composition comprises titanium or aluminium and the second metal composition comprises aluminium oxide.

22. The method according to claim 1, wherein at least one of the first layer and the second layer comprises a glass composition.

23. The method according to claim 22, wherein the glass composition comprises a silicon glass composition.

24. The method according to claim 22, wherein one of the first layer and the second layer comprises a glass composition and the other layer comprises a polymer.

25. The method according to claim 22, wherein one of the first layer and the second layer comprises a glass composition and the other layer comprises silicon.

26. An integrated circuit fabricated using the method according to claim 1.

27. A hard mask layer stack to be used to generate a structure in a substrate, the hard mask layer stack comprising:
a first hard mask layer overlying the substrate, the first hard mask layer having a first etch rate with respect to an etchant; and
a second hard mask layer overlying the substrate, the second hard mask layer having a second etch rate with respect to the etchant, the first etch rate being higher than the second etch rate.
